(19) United States
(12) Patent Application Publication
(10) Pub. No.: US 2013/0250499 A1
(43) Pub. Date: Sep. 26, 2013

(54) ELECTRONIC DEVICE

(71) Applicants: Chang-Yi Tseng, Taipei City (TW); Hung-Chieh Wu, Taipei City (TW); Liang-Jen Lin, Taipei City (TW)

(72) Inventors: Chang-Yi Tseng, Taipei City (TW); Hung-Chieh Wu, Taipei City (TW); Liang-Jen Lin, Taipei City (TW)

(73) Assignee: ASUSTeK COMPUTER INC., Taipei City (TW)

(21) Appl. No.: 13/762,383

(22) Filed: Feb. 8, 2013

(30) Foreign Application Priority Data
Mar. 23, 2012 (TW) 101110214

(51) Int. Cl. H05K 5/02; H05K 5/00

(52) U.S. Cl. CPC H05K 5/0217; H05K 5/0017
USPC 361/679.01

(57) ABSTRACT

An electronic device including a main body, a support arms, and a display is provided. The main body has a positioning portion. A first end of the support arm is pivoted to the main body, and the support arm is telescopic. A second end of the support arm is pivoted to the display. When the display is opened, the support arm rotates such that the display stands, and the display is driven to rotate by retracting the support arm to adjust a tilting angle of the display. At this time, an edge of the display is supported on the positioning portion of the main body.

### CROSS-REFERENCE TO RELATED APPLICATION

This application claims the priority benefit of Taiwan application serial no. 101110214, filed on Mar. 23, 2012. The entirety of the above-mentioned patent application is hereby incorporated by reference herein and made a part of this specification.

### BACKGROUND OF THE INVENTION

1. Field of the Invention

The technical field relates to an electronic device, and more particularly to an electronic device with a display.

2. Description of Related Art

In the information explosion era, electronics have created an inseparable relationship with daily life. As the electronic technology is evolving, new electronics products are coming out with user-friendly improvements and better performance. For example, the tablet personal computer (PC) is convenient in use, and can be placed on a desktop or a lap and operated by utilizing a stylus.

With the development of smart handheld electronic device, the number of a slider or a sliding-type handheld electronic device which combines the tablet PC with an input module has been provided more and more. FIG. 1 is a diagram of a conventional sliding-type handheld electronic device. FIG. 2 is a diagram schematically illustrating the display of FIG. 1 is opened relatively to the main body. FIG. 3 is a diagram schematically illustrating the display of FIG. 1 is opened relatively to the main body in another manner.

Referring to FIG. 1 to FIG. 3, the conventional sliding-type handheld electronic device 50 includes a main body 52 and a display 54, and the main body 52 includes a keyboard 52a. After the display 54 of the sliding-type handheld electronic device 50 slides upward relatively to the main body 52 until a fixed position, and a specific tilting angle is reached with respect to the main body 52, if a standing angle of the display 54 is adjusted, an edge 54a of the display 54 may move toward the keyboard 52a of the main body 52 and hence cover the keyboard 52a (as showing in FIG. 2). Also, the centre of gravity of the display 54 may be shifted to far away from the main body 52, which will cause the display unsteady and unable to be fixed in a position (as shown in FIG. 3) Hence, users are unable to adjust the tilting angle of the display 54 to meet his/her requirements and causes inconvenience.

### SUMMARY OF THE INVENTION

The disclosure provides an electronic device including a main body, two support arms, and a display. The two support arms are connected between the main body and the display. The lengths of the two support arms are adjustable, and the two support arms are connected to the display respectively. When the display is opened, one edge of the display is supported on the main body, and the support arms are expanded or retracted for adjusting a tilting angle of the display.

In one embodiment of the disclosure, the main body includes a positioning portion, and when the display is opened, one edge of the display is supported on the positioning portion of the main body.

In one embodiment of the disclosure, when the edge of the display is moved away from the positioning portion, the display is adapted to be closed to the main body by the rotation of the support arms.

In one embodiment of the disclosure, the support arm includes a first rod and a second rod. The first rod is pivoted to the main body. The second rod is telescopically connected to the first rod and pivoted to the display.

In one embodiment of the disclosure, the first rod includes a plurality of positioning structures. Each of the positioning structures is adapted to position the second rod.

In one embodiment of the disclosure, the electronic device further includes a magnetic component disposed on the positioning portion or the display, wherein the positioning portion is adapted to stop the display from sliding along the main body by a magnetic force of the magnetic component.

The disclosure provides an electronic device including a main body, two support arms, and a display. Each of the two support arms is pivoted to the main body and the display. Each of two sides of the display includes a sliding slot. The two support are slidably disposed on the two sliding slots respectively. When the display is opened, the display is supported on the main body, and the support arm slides in the sliding slot for adjusting a tilting angle of the display.

In one embodiment of the disclosure, the main body includes a positioning portion. When the display is opened, an edge of the display is supported on the positioning portion of the main body.

In one embodiment of the disclosure, when the edge is moved away from the positioning portion, the display is adapted to be closed to the main body by the rotation of the support arms.

In one embodiment of the disclosure, the sliding slot includes a plurality of positioning structures therein, and each of the positioning structures is adapted to position the support arm.

In one embodiment of the disclosure, the electronic device further includes a magnetic component disposed on the positioning portion or the display, wherein the positioning portion is adapted to stop the display from sliding along the main body by a magnetic force of the magnetic component.

Several exemplary embodiments accompanied with figures are described in detail below to further describe the disclosure in details.

### BRIEF DESCRIPTION OF THE DRAWINGS

The accompany drawings are included to provide further understanding, and are incorporated in and constitute a part of this specification. The drawings illustrate exemplary embodiments and, together with the description, serve to explain the principles of the disclosure.

FIG. 1 is a schematic diagram illustrating a conventional sliding-type handheld electronic device

FIG. 2 is a diagram schematically illustrating the display of FIG. 1 is opened relatively to the main body.

FIG. 3 is a diagram schematically illustrating the display of FIG. 1 is opened relatively to the main body in another manner.

FIG. 4 is a diagram schematically illustrating an electronic device according to one embodiment of the disclosure.

FIG. 5 is a diagram schematically illustrating the display of FIG. 4 is opened relatively to the main body.

FIG. 6 is a diagram schematically illustrating the display of FIG. 5 is driven relatively to the main body.

FIG. 7 is an enlarged sectional diagram schematically illustrating the rod and the support arm of FIG. 5.

FIG. 8 is an enlarged sectional diagram schematically illustrating the main body and the display of FIG. 5.

FIG. 9 is a diagram schematically illustrating an electronic device according to another embodiment of the disclosure.

FIG. 10 is a diagram schematically illustrating the display of FIG. 9 is driven relatively to the main body.

FIG. 11 is an enlarged sectional diagram schematically illustrating the display and the support arm of FIG. 9.

FIG. 12 is an enlarged sectional diagram schematically illustrating an electronic device according to still another embodiment of the disclosure.

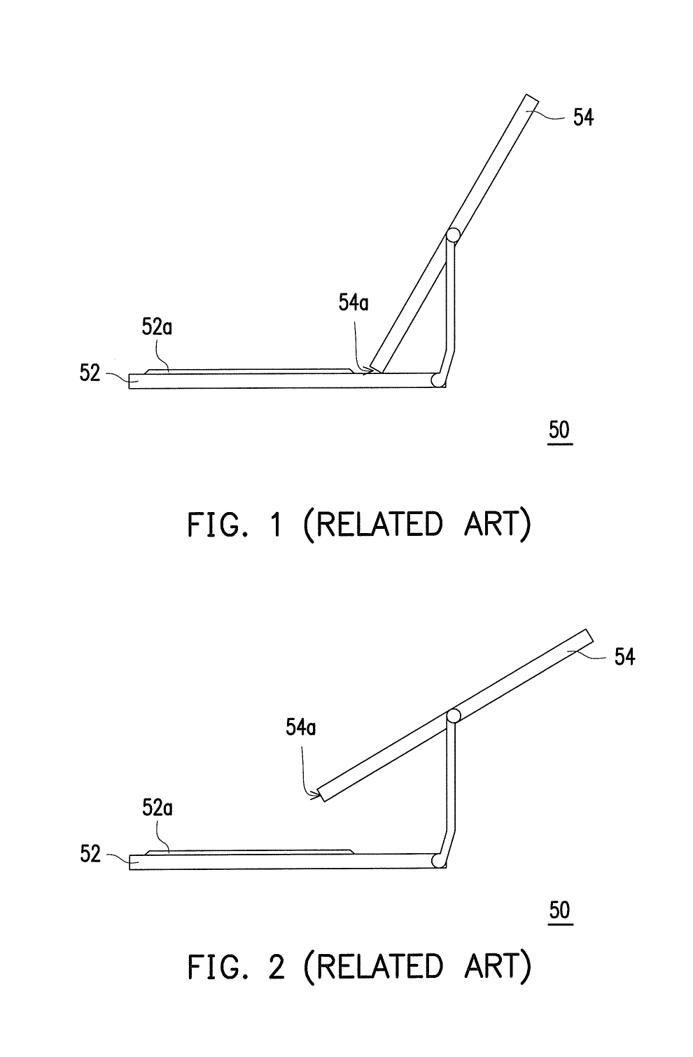

### DETAILED DESCRIPTION OF DISCLOSED EMBODIMENTS

Reference will now be made in detail to the present embodiments of the disclosure, examples of which are illustrated in the accompanying drawings. Wherever possible, the same reference numbers are used in the drawings and description to refer to the same or like part.

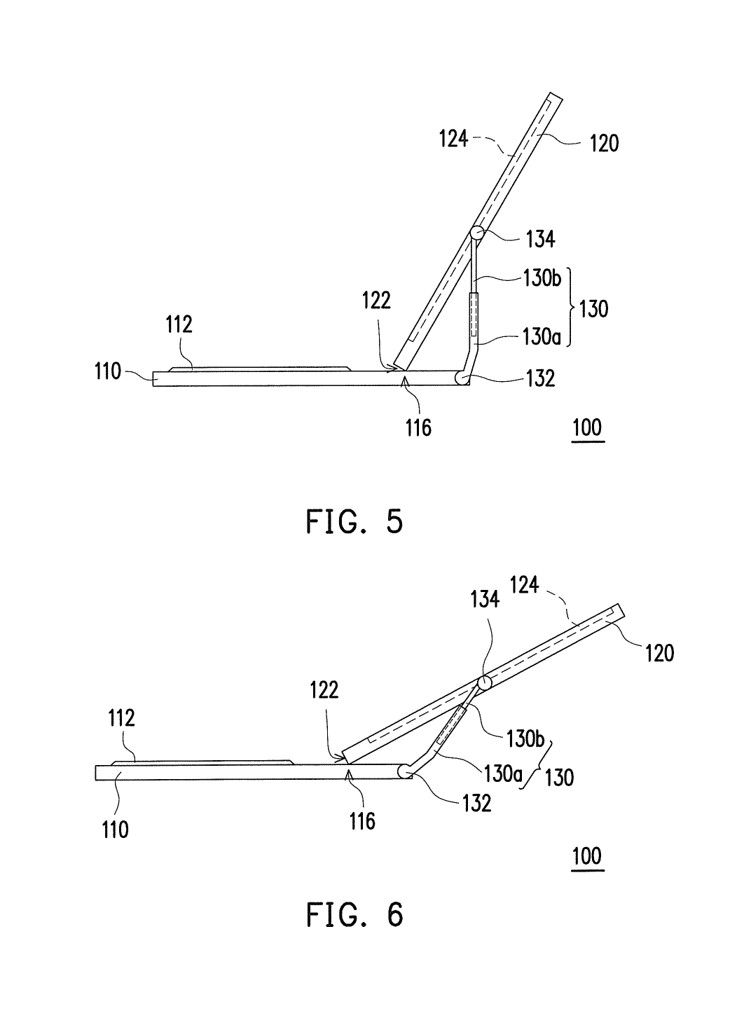

FIG. 4 is a diagram schematically illustrating an electronic device according to one embodiment of the disclosure. FIG. 5 is a diagram schematically illustrating the display of FIG. 4 is opened relatively to the main body. Referring to FIG. 4 and FIG. 5, the electronic device 100 of this embodiment includes a main body 110, a display 120, and two support arms 130. Due to the viewing angle in the diagram, only one support arm 130 is showing and another support arm is covered by the support arm 130 in the diagram.

The electronic device 100 is, for example, a sliding-type handheld electronic device that combines tablet PC (display 120) and an input module (main body 110) together. The main body 110 may include a keyboard 112, and the display 120 includes a display surface 124, such that users are allowed to operate the electronic device 100 by the keyboard 112 and view the image displayed on the display surface 124. The display 120 described can be a touch display. In addition, in other embodiments, the main body 110 may further include one other touch display part that allows inputs from users. However, the disclosure is not limited thereto.

In an embodiment, the main body 110 includes a positioning portion 116. Each of the support anus 130 includes a first end 132 and a second end 134. Each first end 132 is pivoted to the main body 110. Each of two edges of the display 120 is connected to the two second ends 134 of the support arms 130 respectively. In the embodiment, the support arms 130 have an expandable and retractable design. In other words, the lengths of the support arms 130 can be adjusted by the expandable and retractable design. FIG. 4 depicts the closed state of the electronic device 100. When the display 120 is opened, the display 120 slides upward until the position showing in the FIG. 5 by the rotation of the support arms 130, such that the electronic device 100 is opened up from the closed state to the state showing in FIG. 5 for the user to operate. At this time, the display 120 is standing by the support of the support arms 130, and an edge 122 of the display 120 is supported on a positioning portion 116 of the main body 110.

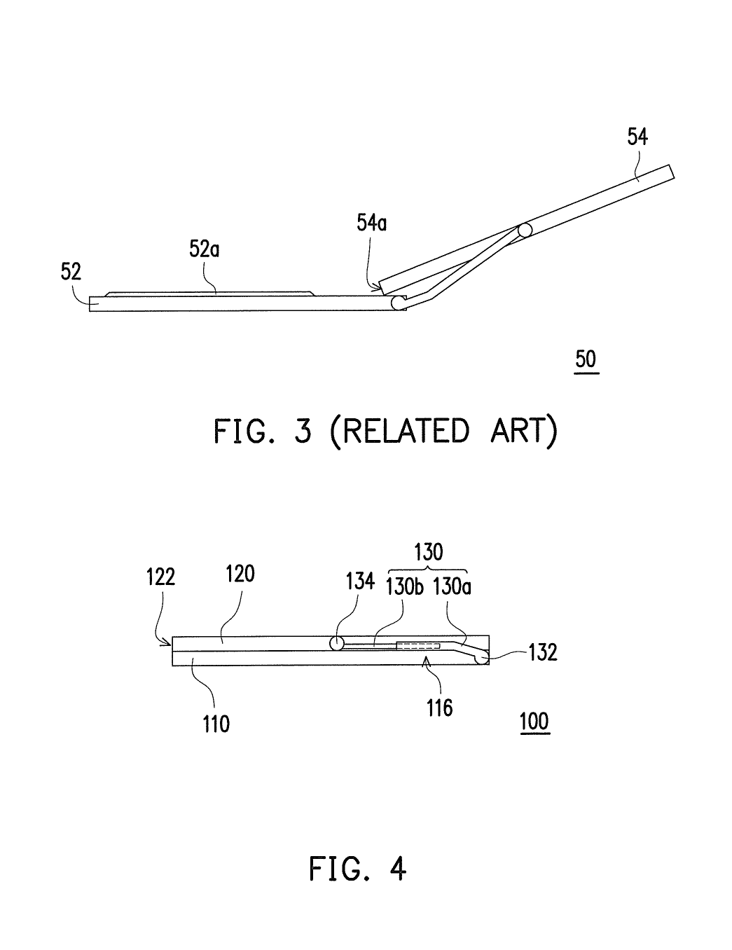

FIG. 6 is a diagram schematically illustrating the display of FIG. 5 is driven relatively to the main body. When the user press the display 120 to adjust the tilting angle of the display 120, the support arms 130 rotates and is retracted to drive the display 120 to rotate from the state showing in FIG. 2 to the state showing in FIG. 3. During the driving process from FIG. 5 to FIG. 6, the positioning portion 116 stops the edge 122 of the display 120 from sliding along the main body 110.

Thus, the design of the support arms 130 can prevent the display 120 from covering the keyboard 112 of the main body 110, and can also prevent the relative displacement of the main body 110 and the display 120 from being too large which cause the centre of the gravity of the display 120 to be unstable, so as to enhance the convenience in use of the electronic device 100. While attempting to put away or carry the electronic device 100, the user can move the edge 122 of the display 120 away from the positioning portion 116 and rotate the support arms 130, so as to drive the display 120 to rotate and close to the main body 110.

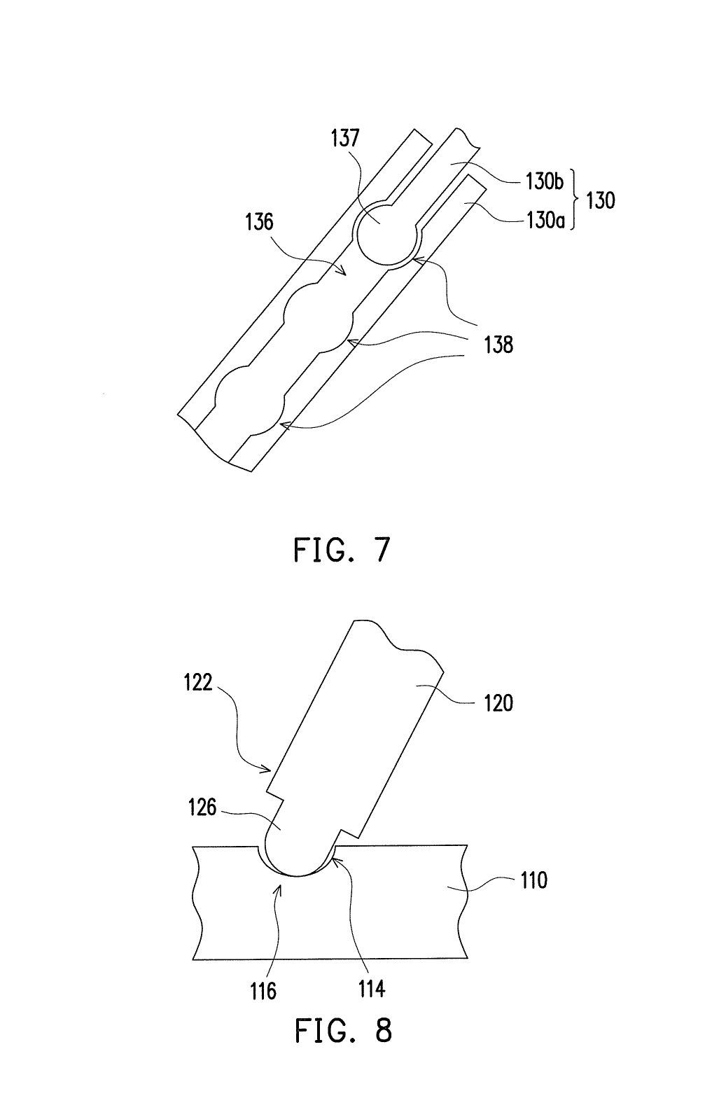

FIG. 7 is an enlarged sectional diagram schematically illustrating the rod and the support arm of FIG. 5. Referring to FIG. 6 and FIG. 7. The support arm 130 includes a first rod 130a and a second rod 130b. The first rod 130a is pivoted to the main body 110, and the second rod 130b is slidably disposed on the first rod 130a and pivoted to the display 120. In other words, the support arms 130 are expanded or retracted by the sliding relationship between the first rod 130a and the second rod 130b. In detail, the first rod 130a of this embodiment includes a containing portion 136 and a plurality of positioning structures 138. A tail end 137 of the second rod 130b is slidably disposed within the containing portion 136. The second rod 130b is adapted to be expanded or retracted at the containing portion 136 with the tail end 137 sliding along the first rod 130a, and each of the positioning structure 138 is adapted to position the tail end 137. When the user adjust the display 120 by rotating it to an appropriate position, the tilting angle of the display 120 can be fixed by the positioning structures 138 which position the tail end 137. In other embodiments, the tail end 137 of the second rod 130b can be positioned in the containing portions 136 by other suitable structures, and the disclosure is not limited thereto.

FIG. 8 is an enlarged sectional diagram schematically illustrating the main body and the display of FIG. 5. Referring to the FIG. 8, the edge 122 of the display 120 includes a protrusion 126. The positioning portion 116 of the main body 110 includes a recess 114. The positioning portion 116 is adapted to prevent the edge 122 from sliding along the main body 110 by the structural interference between the recess 114 and the protrusion 126.

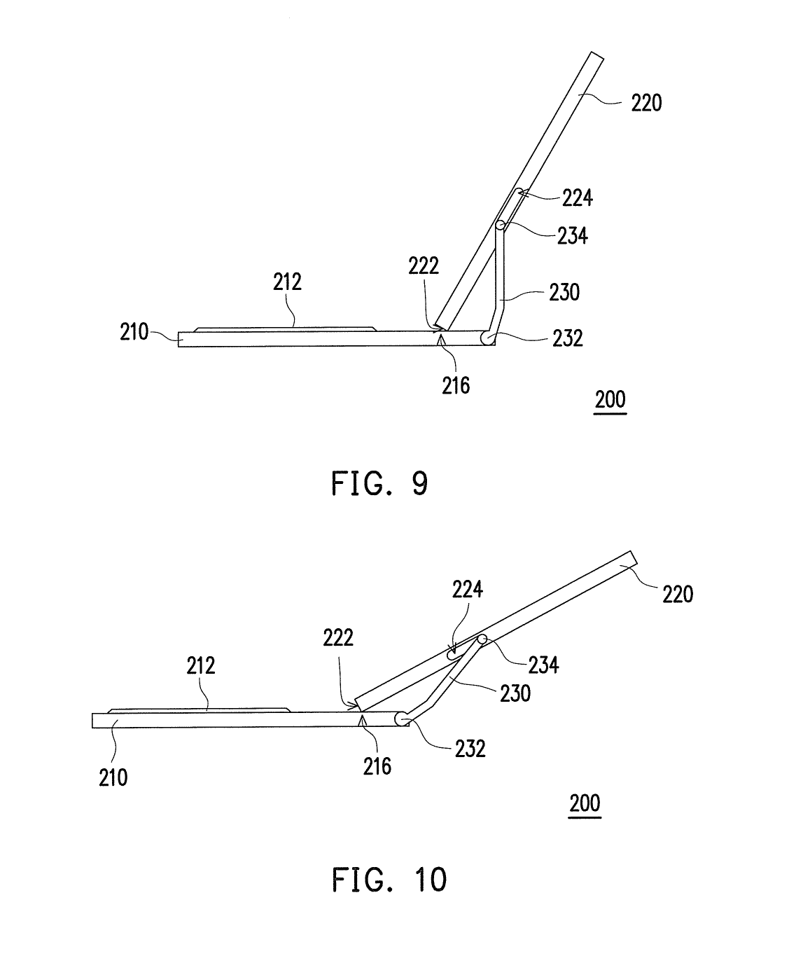

The connection manner of the support arms and display are not limited herein, and the following diagrams are used for further explanation. FIG. 9 is a diagram schematically illustrating an electronic device according to another embodiment of the disclosure. FIG. 10 is a diagram schematically illustrating the display of FIG. 9 is driven relatively to the main body. Due to the viewing angle in the diagram, only one support arm 230 is showing and another support arm is covered by the support arms 230 in the diagram. Referring to FIG. 9 and FIG. 10, in the electronic device 200 of this embodiment, each of two sides of the display 220 includes a sliding slot 224. The first end 232 of the support arm 230 is pivoted to the main body 210, and the second end 234 of the support arm 230 is slidably disposed in the sliding slot 224 of the display 220. When the display 220 is in a position as showing in the FIG. 9, the electronic device 200 is in open state for the user to operate. At this time, the support arms 230 supports the display 220 to stand and an edge 222 of the display 220 is supported on the positioning portion 216 of the main body 210.

When the user press the display 220, the second end 234 of the support aim 230 moves along the sliding slot 224 to drive the display 220 to rotate from the state showing in FIG. 6 to the state showing in FIG. 7, so as to adjust the tilting angle of the display 220. In the driving process of FIG. 6 to FIG. 7, the positioning portion 216 prevents the edge 222 of the display 220 from sliding along the main body 210.

Thus, the design of the support arms 230 can prevent the display 220 from covering the keyboard 212 of the main body 210, and can also prevent the relative displacement of the main body 210 and the display 220 from being too large which cause the centre of the gravity of the display 220 to be unstable, so as to enhance the convenience in use of the electronic device 200. While attempting to put away or carry the electronic device 200, the user can move the edge 222 of the display 220 away from the positioning portion 216 and rotate the support arms 230, so as to drive the display 220 to rotate and close to the main body 210.

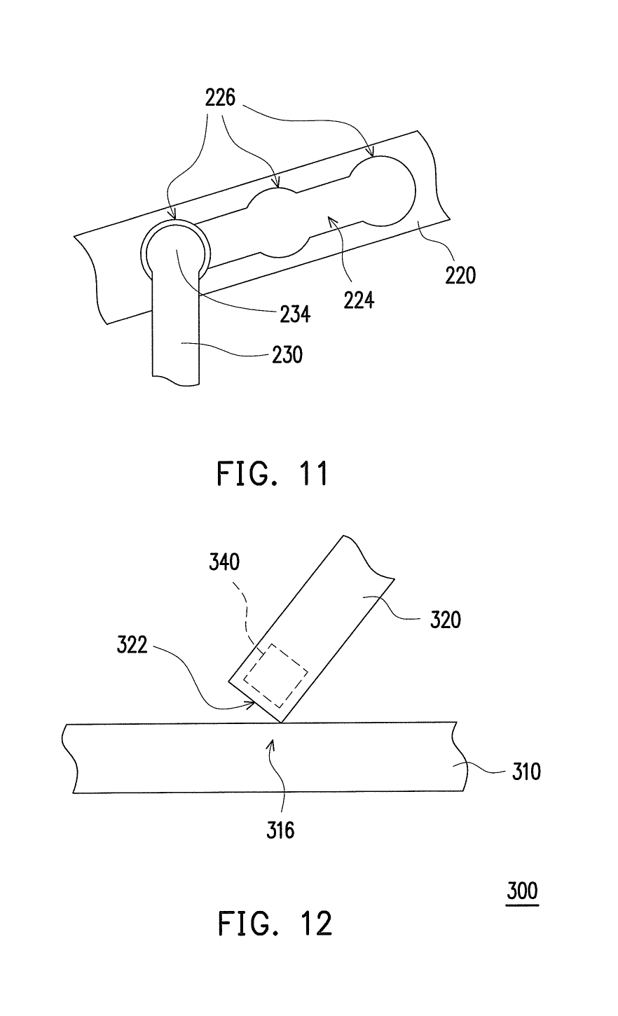

FIG. 11 is an enlarged sectional diagram schematically illustrating the display and the support arm of FIG. 9. Referring to FIG. 9 and FIG. 11, in this embodiment, the sliding slot 224 includes a plurality of positioning structures 226 therein, and each of the positioning structures 226 is adapted to position the second end 234. When the user adjust the display 220 by rotating it to an appropriate position relative to the main body 210, the tilting angle of the display 220 relative to the main body 210 can be fixed by the positioning structures 226 which position the second end 234. In other embodiments, the second end 234 of the support arm 230 can be positioned in the sliding slot 224 by other suitable structures and the disclosure is not limited thereto.

The method of how the positioning portion prevents the edge of the display from moving along the main body is not limited herein, and the following schematics are used for further explanation. FIG. 12 is an enlarged sectional diagram schematically illustrating an electronic device according to still another embodiment of the disclosure. Referring to FIG. 12, the electronic device 300 of this embodiment includes a magnetic component 340. The magnetic component 230 is disposed at the edge 322 of the display 320. The material of the positioning portion 316 of the main body 310 includes metals. The positioning portion 316 prevents the edge 322 of the display 320 from moving along the main body 310 by the magnetic force of the magnetic component 340 applied to the positioning portion 316. In other embodiments, the magnetic component 340 can be disposed in the positioning portion 316, and the material of the display 320 includes metals, such that the positioning portion 316 prevents the edge 322 of the display 320 from moving along the main body 310 by the magnetic force of the magnetic component 340 applied to the display 320. Furthermore, two magnetic components can be disposed in the positioning portion 316 and the display 320 respectively, such that the positioning portion 316 prevents the edge 322 of the display 320 from moving along the main body 310 by the magnetic force between the two magnetic components.

The style of the positioning portion is not limited in the disclosure. In the FIG. 8, the positioning portion 116 prevents the edge 122 from sliding along the main body 210 by the structural interference between the recess 114 and the protrusion 126 of the display 120, and this style of the design can be applied to the electronic device 200 of FIG. 9 and FIG. 10. Moreover, the positioning portion 316 illustrated in the FIG. 12 prevents the edge 322 from moving along the main body 310 by the magnetic force of the magnetic component 340, and this style of the design can be applied to the electronic device 100 of FIG. 5 and FIG. 6 and the electronic device 200 of FIG. 9 and FIG. 10.

Base on the above, in the electronic device of the embodiments of the disclosure, the length of the support arm is adjustable, the support arm is pivoted between the main body and the display (or the first end of the support arm is pivoted to the main body while the second end of the support arm is slidably disposed in the sliding slot of the display), and the positioning portion is disposed on the main body to support the display. By the expanding or retracting of the support arms (or movement by the second end of the support arms along the sliding slots), the display can be rotated to adjust the tilting angle of the display, and the positioning portion can prevent the edge of the display from moving along the main body. Thus, when the user rotate the display to adjust the tilting angle of the display, the display is prevented from covering the main body, and the relative displacement of the main body and the display is prevented from being too large which cause the centre of the gravity of the display to be unstable, so as to enhance the convenience in use of the electronic device.

It will be apparent to those skilled in the art that various modifications and variations can be made to the structure of the disclosed embodiments without departing from the scope of spirit of the disclosure. In view of the foregoing, it is intended that the disclosure cover modifications and variations of this disclosure provided they fall within the scope of the following claims and their equivalents.

What is claimed is:

1. An electronic device, comprising:
a main body;
two support arms, the lengths of the support arms are adjustable; and
a display, the two support arms are connected to the display respectively, the support arms are connected between the main body and the display,
when the display is opened, an edge of the display is supported on the main body, and the support arms are expanded or retracted for adjusting a tilting angle of the display.

2. The electronic device according to claim 1, wherein the main body has a positioning portion, and when the display is opened, the edge of the display is supported on the positioning portion of the main body.

3. The electronic device according to claim 1, wherein when the edge is moved away from the positioning portion, the display is adapted to be closed to the main body by the rotation of the support arms.

4. The electronic device according to claim 1, wherein the support arm comprises:
a first rod pivoted to the main body; and
a second rod telescopically connected to the first rod and pivoted to the display.

5. The electronic device according to claim 4, wherein the first rod has a plurality of positioning structures, and each of the positioning structures is adapted to position the second rod.

6. The electronic device according to claim 1, further comprises a magnetic component disposed on the positioning portion or the display, wherein the positioning portion is adapted to stop the display from sliding along the main body by a magnetic force of the magnetic component.

7. The electronic device according to claim 1, wherein the main body comprises a keyboard or a touch display part.

8. An electronic device, comprising:
a main body;
a display, each of two sides of the display has a sliding slot; and
two support arms, each of the support arms is pivoted to the main body and the display, and the two support arms are slidably disposed on the sliding slots respectively,
when the display is opened, the display is supported on the main body, and the support arm slides in the sliding slot for adjusting a tilting angle of the display.

9. The electronic device according to claim 8, wherein the main body has a positioning portion, and when the display is opened, an edge of the display is supported on the positioning portion of the main body.

10. The electronic device according to claim 9, wherein when the edge is moved away from the positioning portion, the display is adapted to be closed to the main body by the rotation of the support arms.

11. The electronic device according to claim 10, wherein the sliding slot has a plurality of positioning structures therein, and each of the positioning structures is adapted to position the support arm.

12. The electronic device according to claim 8, further comprises a magnetic component disposed on the positioning portion or the display, wherein the positioning portion is adapted to stop the display from sliding along the main body by a magnetic force of the magnetic component.

13. The electronic device according to claim 8, wherein the main body comprises a keyboard or a touch display part.
